(19) United States
(12) Patent Application Publication
(10) Pub. No.: US 2016/0178475 A1
(43) Pub. Date: Jun. 23, 2016

(54) LEAK DETECTION IN LIQUID COOLED COMPUTING SYSTEMS

(71) Applicant: Intel Corporation, Santa Clara, CA (US)

(72) Inventors: Shankar Krishnan, Wilsonville, OR (US); Scott M. Rider, Beaverton, OR (US); Wilson E. Smoak, West Columbia, SC (US)

(21) Appl. No.: 14/574,321

(22) Filed: Dec. 17, 2014

(51) Int. Cl. G01M 3/40; H05K 7/20; G01N 21/80

(52) U.S. Cl. CPC G01M 3/40; G01N 21/80; H05K 7/20772

(57) ABSTRACT

The present disclosure describes embodiments of a computing system having a circuit for detecting a leak of a liquid in the cooling system and associated techniques and configurations. In some embodiments, the computing system includes a server board having a cooling system, and the circuit, wherein the circuit includes a first conducting element disposed on a substrate and coupled to a first voltage and a second conducting element disposed on the substrate and coupled to a second voltage. The first and second conducting elements are proximately disposed near each other, and the proximate positions are selected such that voltage across the conducting elements changes when a liquid is in simultaneous contact with the two conducting elements. In some embodiments, a detection circuit is coupled to the two electrodes to detect when the liquid is in simultaneous contact with the two conducting elements. Other embodiments may be disclosed and/or claimed.

### FIELD

Embodiments of the present disclosure generally relate to the field of systems with liquid cooling, and more particularly, to liquid leak detection circuits, liquid cooled computing systems, and methods in liquid cooled computing systems.

### BACKGROUND

Systems, such as computer server systems, in particular servers designed for super computing, may have a thermal management system to prevent overheating that can damage such systems. An approach to thermal management includes use of liquid cooling systems such as systems that cool specific heat generating devices including microprocessors for example. In this approach, a cooling device may be attached directly to the microprocessor for example, where a fluid is pumped into and out of the cooling device thereby cooling the microprocessor by heat transfer to the fluid. The liquid used in such cooling systems may be a water-based liquid that may have one or more other components such as ethylene or propylene glycol for example. To protect the electronics from damage and short circuiting, liquid cooling systems may have leak detection sensors to detect when a leak occurs of the liquid used in such liquid cooling systems. Prior art sensors for detecting leaks are typically based on external sensing approaches, and such approaches may be carried out at the cabinet (rack) or chassis level of a system. In an external sensing approach, an entire chassis or rack may need to be shut down when a leak occurs because of an inability to identify the location the module having the leak. This down time may be costly to datacenter operators.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a circuit for detecting a leak of a liquid in a cooling system, in accordance with some embodiments.

FIG. 2 schematically illustrates a circuit for detecting a leak of a liquid in a cooling system, wherein a liquid drop contacts circuit elements, in accordance with some embodiments.

FIG. 3 schematically illustrates a circuit with interdigitated electrodes for detecting a leak of a liquid in a cooling system, in accordance with some embodiments.

FIG. 4 schematically illustrates a circuit with interdigitated electrodes for detecting a leak of a liquid in a cooling system, wherein one electrode is coupled to ground and the other electrode is coupled to Vcc, in accordance with some embodiments.

FIG. 5 schematically illustrates a circuit with capacitor plates for detecting a leak of a liquid in a cooling system, in accordance with some embodiments.

FIG. 6 schematically illustrates a circuit with capacitor plates for detecting a leak of a liquid in a cooling system, wherein a liquid drop contacts circuit elements, in accordance with some embodiments.

FIG. 7 schematically illustrates a circuit with interdigitated electrodes and a porous material coupled to the electrodes for detecting a leak of a liquid in a cooling system, in accordance with some embodiments.

FIG. 8 schematically illustrates a circuit with capacitor plates with a porous material coupled to the plates for detecting a leak of a liquid in a cooling system, in accordance with some embodiments.

FIG. 9 schematically illustrates a porous pad for adsorbing liquid and reporting pH of the liquid, in accordance with some embodiments.

FIG. 10 schematically illustrates a substrate with a computing element that is cooled by a liquid cooling system, wherein the substrate includes a circuit for detecting a leak of a liquid in the liquid cooling system as described herein, in accordance with some embodiments.

FIG. 11 schematically illustrates a substrate with a computing element that is cooled by a liquid cooling system, wherein the computing element is covered by a shroud and the substrate includes a circuit for detecting a leak of a liquid in the liquid cooling system as described herein, in accordance with some embodiments.

FIG. 12 schematically illustrates a method for detecting a liquid leak in a computing node, in accordance with some embodiments.

FIG. 13 schematically illustrates a method for detecting a leak of a cooling liquid at a computing node in a liquid cooled computing system, in accordance with some embodiments.

FIG. 14 schematically illustrates an apparatus for computing that includes a circuit for detecting a leak of a liquid in a cooling system as described herein, in accordance with some embodiments.

### DETAILED DESCRIPTION

Embodiments of the present disclosure describe a liquid cooled system, e.g. a liquid cooled rack computing system, having a circuit for detecting a leak of a liquid in the liquid cooled system, and associated techniques and configurations. In embodiments, the circuit may be disposed on server boards with respective liquid cooling systems. In the following description, various aspects of the illustrative implementations are described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group), and/or memory (shared, dedicated, or group) that execute one or more software or firmware programs, a combinational logic circuit, and/or other suitable components that provide the described functionality.

As used herein, the term conducting/conductive liquid may be used to describe aqueous based liquids/solutions as described herein by example. As used herein, the term non-conducting/conductive liquid may be used to describe non-aqueous liquids such as oils or silicone liquids for example, where conductivity is generally lower than aqueous based liquids/solutions.

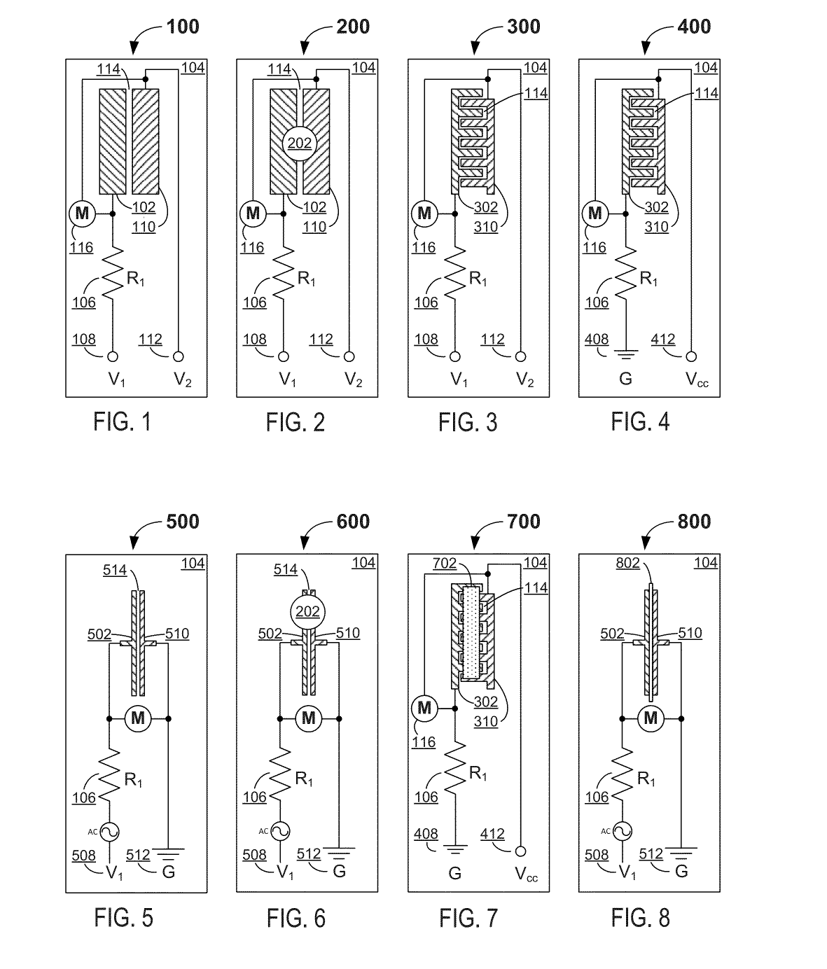

FIG. 1 schematically illustrates a circuit for detecting a leak of a liquid in a cooling system, in accordance with some embodiments. In some embodiments, the circuit 100 may have a first conducting element 102 disposed on a substrate 104 and coupled to a resistor 106 that is coupled to a first voltage 108 and a second conducting element 110 disposed on the substrate 104 and coupled to a second voltage 112, wherein the first and second conducting elements 102, 110 are proximately disposed near each other 114, and the proximate positions 114 are selected such that voltage, current, impedance, or other electrical measurement 116 across the conducting elements 102, 110 changes when a liquid (FIG. 2, 202) is in simultaneous contact with the two conducting elements 102, 110. In some embodiments, the liquid 202 may be an aqueous liquid or a non-aqueous liquid. In some embodiments, the conducting elements 102, 110 may be spaced apart approximately 50 to 100 micrometers from each other. In some embodiments, the conducting elements 102, 110 may be spaced apart approximately 100 micrometers or greater from each other. In some embodiments, the conducting elements 102, 110 may be spaced apart approximately 500 micrometers or greater from each other. In some embodiments, the conducting elements 102, 110 are traces on a printed circuit board such as a motherboard. In some embodiments, the conducting elements 102, 110 may be or include replaceable components. In some embodiments, the substrate 104 may be a semiconductor substrate material. In some embodiments, the substrate 104 may be composite substrate material and/or a ceramic substrate material. In some embodiments, the substrate 104 may be a printed circuit board. In some embodiments, the substrate 104 may be a motherboard of an apparatus for computing such as a personal computer, a server, or a super computer for example. In some embodiments, the resistor 106 may not be present. In some embodiments, the resistor may not be present and the first and second voltages may be nodes connected to a circuit for detecting when a liquid makes simultaneous contact with the two conducting elements. In some embodiments, the circuit for detecting when a liquid makes simultaneous contact with the two conducting elements may be comprised of an RC circuit, an oscillator circuit, or another circuit where the conducting elements may be a circuit element that has a measurable change in property when a liquid is in simultaneous contact with the two conducting elements. In some embodiments, the circuit 100 may be on a printed circuit board (PCB). In some embodiments, the circuit 100 may be on a PCB in an individual blade/server/sled of a rack system. In some embodiments, the circuit 100 coupled to a PCB in an individual blade/server/sled of a rack system allows determination of which blade/server/sled in a rack system has been exposed to liquid that has leaked from a liquid cooling system.

FIG. 2 schematically illustrates a circuit for detecting a leak of a liquid in a cooling system, wherein a liquid drop 202 contacts circuit elements 102, 110, in accordance with some embodiments. The circuit embodiment 200 of FIG. 2 may comport with embodiments of the circuit 100 for detecting a leak of a liquid in a cooling system of FIG. 1 with the addition of a liquid drop 202 in simultaneous contact with the first conducting element 102 and the second conducting element 110. In some embodiments, the liquid drop 202 may provide a conductive pathway between the two conducting elements 102, 110. In some embodiments, the conductive pathway may be measured 116 by a change in an electrical property of circuit 200, such as a change in voltage, impedance, or current across the conducting elements 102, 110. In some embodiments, the liquid drop may be simultaneously covering both conducting elements 102, 110 and/or may be between the conducting elements while in simultaneous contact with both conducting elements 102, 110. In some embodiments, the liquid drop 202 may be an aqueous based solution such as water or water with soluble solids and/or liquids or a non-aqueous liquid. In some embodiments, the liquid drop 202 may be water mixed with a glycol. In some embodiments, the liquid drop 202 may be a mixture of water, ethylene glycol, and/or propylene glycol.

FIG. 3 schematically illustrates a circuit with interdigitated electrodes for detecting a leak of a liquid in a cooling system, in accordance with some embodiments. The circuit embodiment 300 of FIG. 3 may comport with embodiments of the circuit 100 of FIG. 1 and/or the circuit 200 of FIG. 2, with the substitution of interdigitated electrodes 302, 310. In some embodiments, a first interdigitated electrode 302 is substituted for the first conducting element 102. In some embodiments, a second interdigitated electrode 310 is substituted for the second conducting element 110. In some embodiments, both conducting elements 102, 310 are substituted by interdigitated electrodes 302, 310. In some embodiments, the interdigitated electrodes 302, 310 may be a geometric shape, a curvilinear shape, and/or a circular shape.

FIG. 4 schematically illustrates a circuit with interdigitated electrodes for detecting a leak of a liquid in a cooling system, wherein one electrode 302 is coupled to ground 408 and the other electrode 310 is coupled to Vcc 412, 400, in accordance with some embodiments. The circuit embodiment 400 of FIG. 4 may comport with embodiments of the circuit 100 of FIG. 1, the circuit 200 of FIG. 2, and/or the circuit 300 of FIG. 3, with the substitution of ground 408 for the first voltage source 108 and V_{cc} 412 for the second voltage source 112. In some embodiments, the voltage of the first electrode 302 becomes non-zero when a liquid simultaneously contacts the two electrodes 302, 310.

FIG. 5 schematically illustrates a circuit with capacitor plates for detecting a leak of a liquid in a cooling system, in accordance with some embodiments. The circuit embodiment 500 of FIG. 5 may comport with embodiments of the circuit 100 of FIG. 1, the circuit 200 of FIG. 2, the circuit 300 of FIG. 3, and/or the circuit 400 of FIG. 4, with the substitution of a first capacitor plate 502 for the first conducting element and a second capacitor plate 510 for the second conducting element 110 and the substitution of an AC voltage source 508 for the first voltage source 108 and ground 512 for the second voltage source 112. In some embodiments, the resistor 106 and the capacitor plates 502, 510 form a circuit with an RC time constant. In some embodiments, the position of the capacitor plates 502, 510 are proximate to each other such that the RC time constant changes when a liquid drop (FIG. 6, 202) is in simultaneous contact with the capacitor plates 502, 510.

FIG. 6 schematically illustrates a circuit with capacitor plates for detecting a leak of a liquid in a cooling system, wherein a liquid drop contacts circuit elements 600, in accordance with some embodiments. The circuit embodiment 600 of FIG. 6 may comport with embodiments of the circuit 100 of FIG. 1, the circuit 200 of FIG. 2, the circuit 300 of FIG. 3, the circuit 400 FIG. 4, and/or the circuit 500 of FIG. 5 with the addition of a liquid drop 202 in simultaneous contact with the first capacitor plate 502 and the second capacitor plate 510. In some embodiments, the liquid drop 202 may change the capacitance of the capacitor plates 502, 510. In some embodiments, the capacitance change results in a change in the RC time constant of the circuit 600.

FIG. 7 schematically illustrates a circuit with interdigitated electrodes and a porous material coupled to the electrodes for detecting a leak of a liquid in a cooling system 700, in accordance with some embodiments. The circuit embodiment 700 of FIG. 7 may comport with embodiments of the circuit 100 of FIG. 1, the circuit 200 of FIG. 2, the circuit 300 of FIG. 3, the circuit 400 of FIG. 4, the circuit 500 of FIG. 5, and/or the circuit 600 FIG. 6, wherein a porous pad 702 is coupled to electrodes 302, 310. In some embodiments, the porous pad 702 may be coupled on a surface of the two electrodes 302, 310 and/or the porous pad 702 may be coupled between the two electrodes 302, 310. In some embodiments, the porous pad 702 may extend beyond an area occupied by the electrodes 302, 310. In some embodiments, the porous pad 702 may be in contact with a component of a liquid cooling system.

FIG. 8 schematically illustrates a circuit with capacitor plates with a porous material coupled to the plates for detecting a leak of a liquid in a cooling system 800, in accordance with some embodiments. The circuit embodiment 800 of FIG. 8 may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, and/or the circuit 700 FIG. 7, wherein a porous pad 802 is coupled to capacitor plates 502, 510. In some embodiments, the porous pad 802 may be coupled on a surface of the two capacitor plates 502, 510 and/or the porous pad 802 may be coupled between the two capacitor plates 502, 510. In some embodiments, the porous pad 802 may extend beyond an area occupied by two capacitor plates 502, 510. In some embodiments, the porous pad 802 may be in contact with a component of a liquid cooling system.

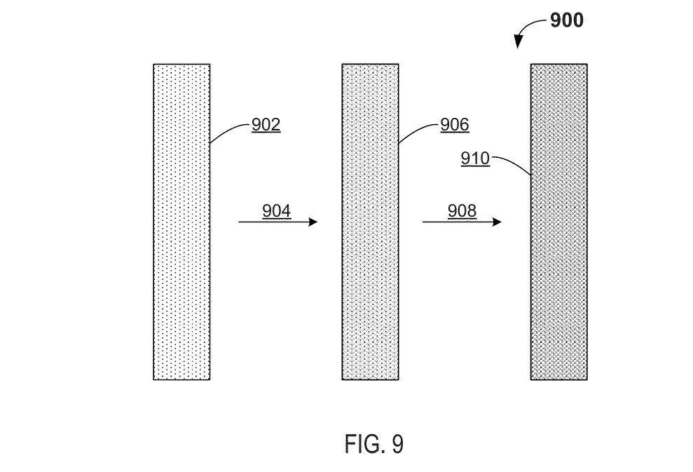

FIG. 9 schematically illustrates a porous pad for adsorbing liquid and reporting pH of the liquid, in accordance with some embodiments. The embodiment of FIG. 9, collectively denoted as 900, may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, the circuit 700 FIG. 7, and/or the circuit 800 of FIG. 8, wherein the porous pad is shown by itself. In some embodiments, the porous pad 902 may have no other additives and may be coupled to the conducting elements of FIGS. 1-8. In some embodiments, an pH reporter compound is added 904 to the porous pad 902 to provide a porous pad with the pH reporter 906. In some embodiments, the porous pad with the pH report 906 contacts an aqueous based cooling liquid 908 and reports the pH by a change in color or other property 910. In some embodiments, the porous pad may be an indicator of a leak when the porous pad 902 comes on contact with a cooling liquid 908 even after the cooling liquid 908 has evaporated out of the porous pad 902. In some embodiments, the indicator may be a cooler change of the porous pad 902.

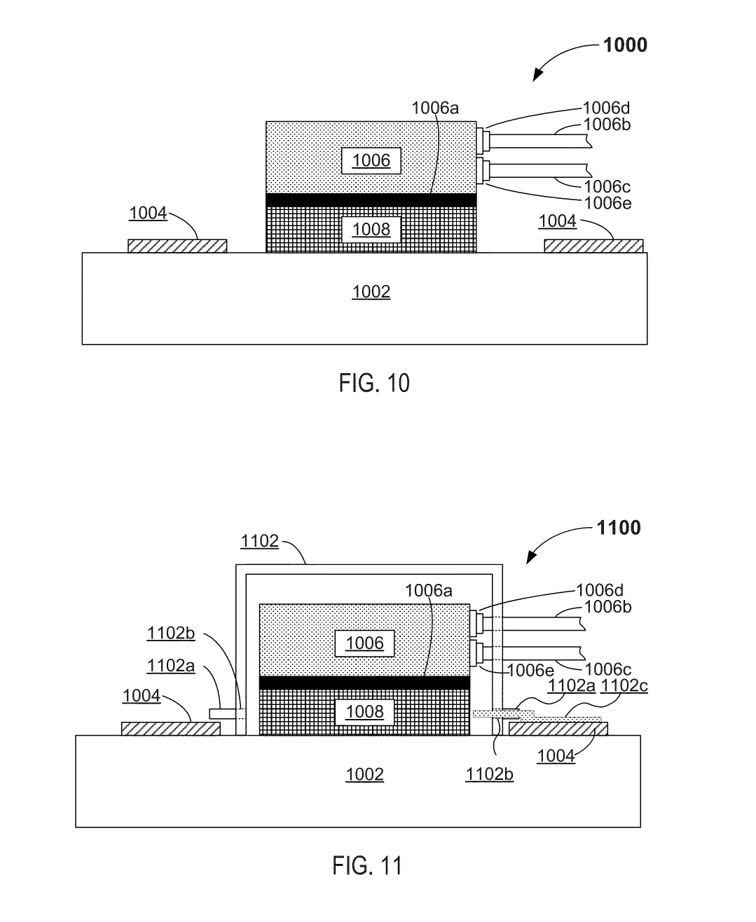

FIG. 10 schematically illustrates a substrate 1002 with a computing element 1008 that is cooled by a liquid cooling system, wherein the substrate includes a circuit for detecting a leak of a liquid 1004 from a liquid cooling system as described herein, in accordance with some embodiments. The computing embodiment 1000 of FIG. 10 may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, the circuit 700 FIG. 7, the circuit 800 of FIG. 8, and/or the pad 900 of FIG. 9. In some embodiments, a computing element 1008 may be coupled to a substrate 1002. In some embodiments, the computing element 1008 may be thermally coupled with a component 1006 of a liquid cooling system. In some embodiments, the component 1006 of the liquid cooling system may have a heat transfer component/thermal interface material (TIM) 1006a coupled to the computing device 1008 for removing heat from computing device 1008. In some embodiments, the component 1006 of the liquid cooling system may have a cooling liquid circulating through the component 1006 by an input port 1006b and an exit port 1006c for the cooling liquid. In some embodiments, input port is coupled by an input coupler 1006d and output port is coupled by an output port couple 1006e. In some embodiments, the cooling liquid is lower in temperature when in the input port 1006b than in the exit port 1006c. In some embodiments, one or more circuits 1004 for detecting a leak of a liquid from the cooling system 1006 may be coupled to the substrate 1002 and positioned proximately near the computing element 1008 such that a leak of cooling liquid from the component 1006 of the liquid cooling system will contact one of the circuits 1004. In some embodiments, one or more circuits 1004 for detecting a leak of a liquid from the cooling system 1006 may be coupled to the substrate 1002 and positioned proximately near the couplers 1006d, 1006e such that a leak of cooling liquid from the couplers 1006d, 1006e of the liquid cooling system will contact one of the circuits 1004. In some embodiments, the circuits 1004 for detecting a leak of a liquid from the cooling system 1006 may be one or more of the embodiments described herein and schematically illustrated herein for some embodiments in FIGS. 1-9. In some embodiments, when a leak occurs and contacts one or more of the circuits 1004, the leak contacts conducting elements of the one or more contacted circuits 1004, as described herein and further illustrated in FIGS. 1-9 for some embodiments.

FIG. 11 schematically illustrates a substrate 1002 with a computing element 1008 that is cooled by a liquid cooling system, wherein the computing element is covered by a shroud 1102 and the substrate 1002 includes one or more circuits 1004 for detecting a leak of a liquid 1004 from the liquid cooling system 1006 as described herein, in accordance with some embodiments. The computing embodiment 1100 of FIG. 11 may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, the circuit 700 FIG. 7, the circuit 800 of FIG. 8, the pad 900 of FIG. 9, and/or the system 1000 of FIG. 10, with the addition of the shroud 1102. In some embodiments, a shroud 1102 may be coupled to a substrate 1002 or computing element 1008. In some embodiments, the shroud may have an input line 1006b and an output line 1006c for liquid coolant to pass through the shroud 1102. In some embodiments, the shroud 1102 may have holes 1102a passing through 1102b the shroud 1102 for directing leaking cooling liquid to one or more circuits 1004 for detecting leaking liquid. In some embodiments, a porous pad may be coupled to the holes 1102a and pass through the shroud 1102 through the holes 1102b and be coupled to one or more circuits 1004 for detecting the leaking liquid. In some embodiments, the porous pad may be present only on the circuit, as described herein and illustrated for some embodiments in FIGS. 1-9. In some embodiments, the porous pad may pass all the way through the shroud 1102 through holes 1102a and couple to one or more circuits 1004. In some embodiments, the porous pad may contact computing element 1008. In some embodiments, the shroud does not completely cover the computing element 1008. In some embodiments, the connectors 1008d, 1008e are inside the shroud.

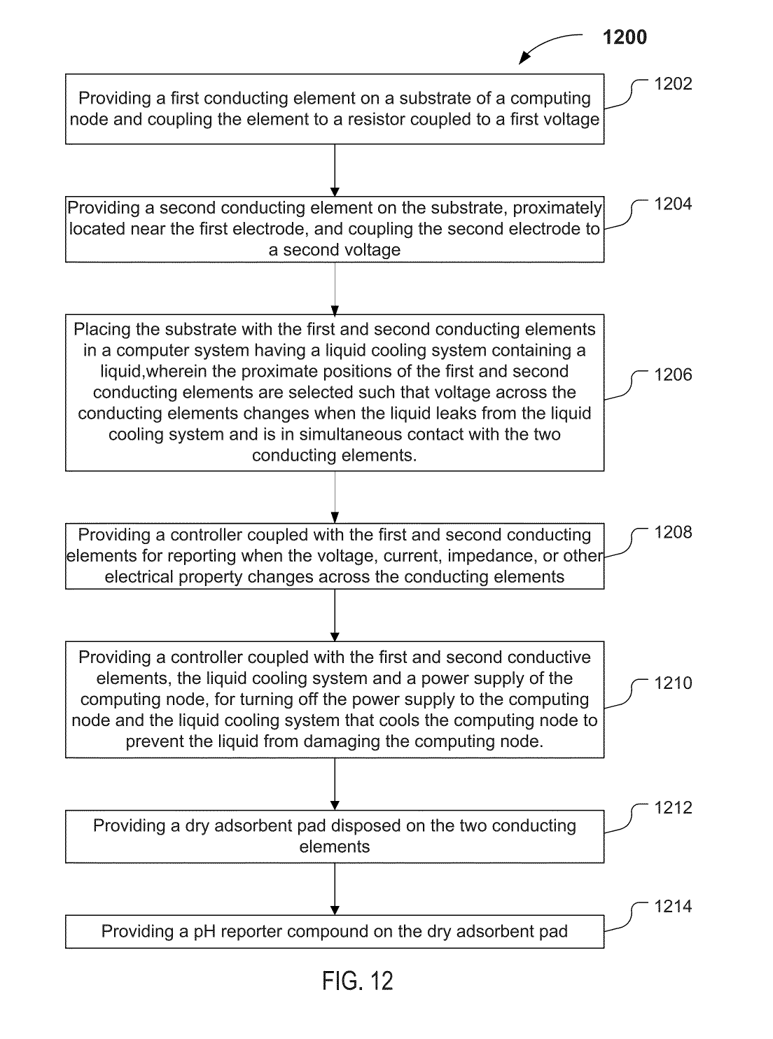

FIG. 12 schematically illustrates a method 1200 for detecting a liquid leak in a system, e.g., a computing node, in accordance with some embodiments. The process embodiment 1200 of FIG. 12 may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, the circuit 700 FIG. 7, the circuit 800 of FIG. 8, the pad 900 of FIG. 9, the system 1000 of FIG. 10, and/or the system 1100 of FIG. 11. In some embodiments, the method for detecting liquid leak in a computing node 1200 may be comprised of providing a first conducting element on a substrate (e.g., of a computing node) where the first conducting element may be coupled to a resistor that may be coupled to a first voltage 1202, providing a second conducting element on the substrate where the second conducting element may be proximately located near the first electrode and may be coupled to a second voltage, 1204, and placing the substrate with the first and second conducting elements in a system having a liquid cooling system containing a liquid, 1206, wherein the proximate positions of the first and second conducting elements are selected such that voltage, current, impedance, or another circuit property across the conducting elements changes when the liquid leaks from the liquid cooling system and is in simultaneous contact with the two conducting elements. In some embodiments, the resistor may be absent, and the first and second voltages may be nodes coupled to a circuit for detecting a change in electrical properties of the conducting elements when a liquid simultaneously contacts the two conducting elements. In some embodiments, the liquid is an aqueous liquid or a non-aqueous liquid as described herein. In some embodiments, the method 1200 may further comprise providing a controller coupled with the first and second conducting elements for reporting when the voltage, current, impedance, or other electrical property changes across the conducting elements, 1208. In some embodiments, the voltage may move toward zero across the conducting elements when a liquid simultaneously contacts the two conducting elements. In some embodiments, the method 1200 may further comprise providing a controller coupled with the first and second conductive elements, the liquid cooling system and a power supply of the computing node, 1210, where the controller turns off and/or signals that the power supply to the computing node and/or the liquid cooling system that cools the computing node to prevent the liquid from damaging the computing node. In some embodiments, the method 1200 may further comprise providing a dry porous pad disposed on the two conducting elements, 1212. In some embodiments, the method 1200 may further comprise providing a pH reporter compound on the dry porous pad, 1214.

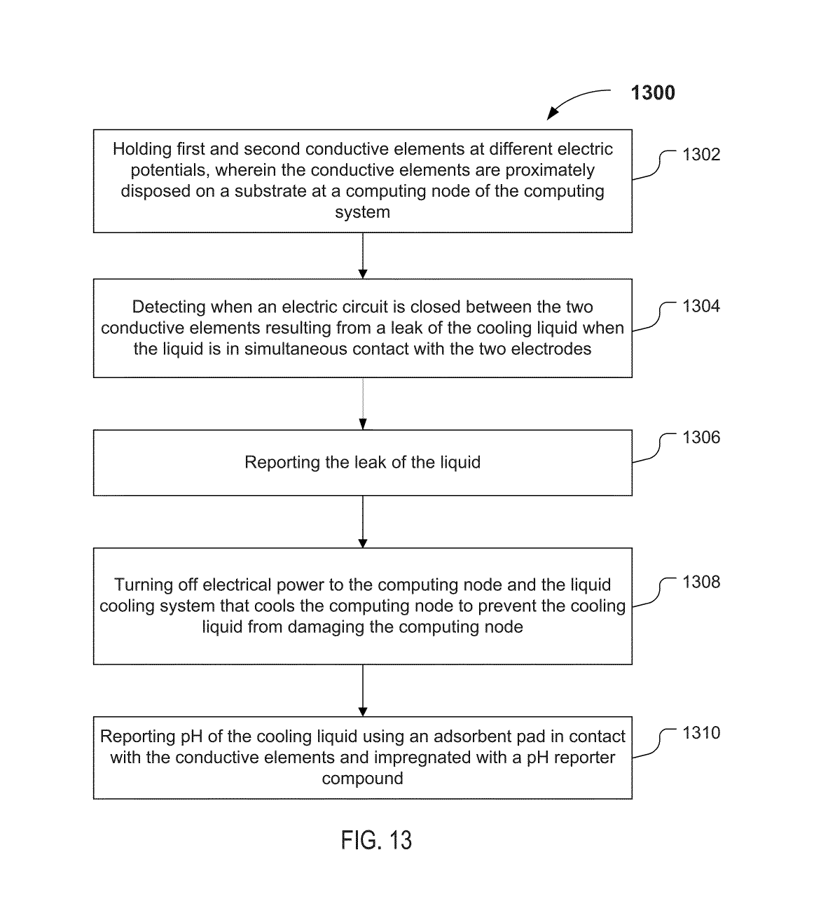

FIG. 13 schematically illustrates a method 1300 for detecting a leak of a cooling liquid at a system (e.g., a computing node) that is liquid cooled, in accordance with some embodiments. The method embodiment 1300 of FIG. 13 may comport with embodiments of the circuit 100 of FIG. 1, the circuit 200 of FIG. 2, the circuit 300 of FIG. 3, the circuit 400 of FIG. 4, the circuit 500 of FIG. 5, the circuit 600 FIG. 6, the circuit 700 FIG. 7, the circuit 800 of FIG. 8, the pad 900 of FIG. 9, the system 1000 of FIG. 10, the system 1100 of FIG. 11, and/or the method 1200 of FIG. 12. In some embodiments, the method 1300 may be comprised of holding first and second conductive elements at different electric potentials, 1302, wherein the conductive elements are proximately disposed on a substrate at system (e.g., a computing node of a computing system); and detecting when an electric circuit is closed between the two conductive elements resulting from a leak of the cooling liquid when the liquid is in simultaneous contact with the two electrodes, 1304.

In some embodiments, the method 1300 may further comprise reporting the leak of the liquid, 1306. In some embodiments, the method 1300 may further comprise turning off electrical power to a module of the system (e.g., one of the computing nodes of a multi-node computing system) and/or the liquid cooling system that cools the module to prevent the cooling liquid from damaging the module, 1308. In some embodiments, the method 1300 may further comprise reporting pH of the cooling liquid using an porous pad in contact with the conductive elements and impregnated with a pH reporter compound, 1310.

Various operations of FIGS. 12-13 are described as multiple discrete operations in turn, in a manner that is most helpful in understanding the claimed subject matter. However, the order of description should not be construed as to imply that these operations are necessarily order dependent.

Embodiments of the present disclosure may be implemented into a system using any suitable hardware and/or software to configure as desired. FIG. 14 schematically illustrates an apparatus for computing 1400 that includes a circuit for detecting a leak of a liquid in a cooling system as described herein, in accordance with some embodiments, and as shown in FIGS. 1-11. In some embodiments, the methods described in FIGS. 12-13 may be practiced on the embodiment of FIG. 14, as well as the embodiments of FIGS. 1-11. The apparatus for computing 1400 may house a board such as motherboard 1402 (e.g., in housing 1426). The motherboard 1402 may include a number of components, including but not limited to a processor 1404, liquid cooling system components 1406, leak detection circuit 1408, chipset 1410, memory 1412, slots 1414, computer bus interface 1416, LAN controller 1418, and ports 1420. The chipset 1410 may include a communications chip. The components may be physically and electrically coupled to the motherboard 1402 and may include other components. The term “processor” may refer to any device or portion of a device that processes electronic data from registers and/or memory to transform that electronic data into other electronic data that may be stored in registers and/or memory.

In some embodiments, the liquid cooling system components 1406 may include routing for the liquid coolant, heat transfer devices for removing heat from devices that are liquid cooled and transferring that heat to the liquid coolant, and pumping devices for pumping the liquid coolant. In some embodiments, the leak detection circuit 1408 may include one or more leak detection circuits as illustrated in FIGS. 1-13 and as described herein. In some embodiments, the leak detection circuit 1408 may be implemented at least in part as a trace line on the motherboard 1402.

Depending on applications, the apparatus for computing 1400 may include other components that may or may not be physically and electrically coupled to the motherboard 1402. These other components may include, but are not limited to, a liquid cooling system, interface devices (keyboard, display, mouse), memory, a graphics processor, a digital signal processor, a crypto processor, a chipset, an antenna, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In further implementations, another component (e.g., processor device or other integrated circuit device) housed within the apparatus for computing 1400 may include a circuit for detecting a leak of a liquid in a cooling system, as described herein and in FIGS. 1-13. In various implementations, the apparatus for computing 1400 may be a computer system, a server, a rack server, a blade server, and a super computer system. In further implementations, the apparatus for computing 1400 may be any other electronic device that processes data.

Various components of the apparatus for computing 1400 shown as being comprised on the motherboard 1402 are shown as an illustration of the embodiment and are not intended to be limiting.

An integrated sensor arrangement that can pinpoint a particular module of a liquid cooled system having a leak would allow an operator to shut down only that module have been described. The approach may provide minimized disruption and/or costs caused by a leak in a multi-module system, since the entire chassis or rack containing the modules may not need to be completely shut down.

### EXAMPLES

According to various embodiments, the present disclosure describes a circuit for detecting a leak of a liquid in a cooling system, e.g., a liquid leak from a cooling system of a server board of a rack system. Example 1 may be a rack system for computing, having a number of server boards, wherein at least one of the server boards includes a liquid cooling system, and a circuit for detecting a leak of a liquid in the cooling system. The circuit may include a first conducting element disposed on a substrate that is coupled to a first voltage; and a second conducting element disposed on the substrate and coupled to a second voltage, wherein the first and second conducting elements are proximately disposed near each other, and the proximate positions are selected such that voltage across the conducting elements changes when a liquid is in simultaneous contact with the two conducting elements.

Example 2 may be Example 1, wherein the liquid is a conductive liquid, the two conducting elements are interdigitated electrodes, a resistor is coupled between the first conducting element and the first voltage, and the voltage across the conducting elements moves toward zero when the conductive liquid is in simultaneous contact with the two interdigitated electrodes.

Example 3 may be Example 2, wherein the first voltage is ground and the second voltage is an integrated circuit power supply voltage (Vcc), wherein the proximate positions are selected such that voltage of the first electrode becomes non-zero when the conductive liquid is in simultaneous contact with the two interdigitated electrodes.

Example 4 may be Example 1, wherein the first conducting element is a first plate of a capacitor and the second conducting element is a second plate of the capacitor, wherein the first voltage is an AC voltage and the second voltage is ground, wherein the resistor and the capacitor form a circuit with an RC time constant, wherein proximate positions of the plates of the capacitor are selected such that the RC time constant changes when the liquid is in simultaneous contact with the two plates of the capacitor.

Example 5 may be any one of Examples 1-4, further comprising a dry porous pad disposed on the two conducting elements.

Example 6 may be Example 5, wherein the dry porous pad is impregnated with a pH reporter compound.

Example 7 may be Example 6, wherein the pH reporter compound is a halochromic chemical species.

Example 8 may be an apparatus for computing. The apparatus may include a number computing boards, wherein at least one of the computing board includes a substrate; one or more computing elements disposed on the substrate; a first conducting element disposed on the substrate that is coupled to a first voltage; and a second conducting element disposed on the substrate and coupled to a second voltage, wherein the first and second conducting elements are proximately disposed near each other, and the proximate positions are selected such that voltage across the conducting elements changes when a liquid is in simultaneous contact with the two conducting elements.

Example 9 may be Example 8, wherein the liquid is a conductive liquid, the two conducting elements are interdigitated electrodes, a resistor is coupled between the first conducting element and the first voltage, and the voltage across the conducting elements moves toward zero when a liquid is in simultaneous contact with the two interdigitated electrodes.

Example 10 may be Example 9, wherein the first voltage is ground and the second voltage is an integrated circuit power supply voltage (Vcc), wherein the proximate positions are selected such that voltage of the first electrode becomes non-zero when a conductive liquid is in simultaneous contact with the two interdigitated electrodes.

Example 11 may be Example 10, further including a liquid cooling system containing the conductive liquid, wherein the liquid cooling system is configured to cool at least one of the computing elements on the substrate, wherein the electrodes on the substrate are configured to have a leak of the conductive liquid simultaneously contact the two electrodes when the liquid cooling system has the leak.

Example 12 may be Example 11, wherein a shroud with at least one hole is coupled to the substrate proximate to at least one of the computing elements cooled by the liquid cooling system, wherein the shroud is configured to channel the conductive liquid to the electrodes when the liquid cooling system leaks at the location of the at least one computing elements cooled by the liquid cooling system.

Example 13 may be Example 8, wherein the first conducting element is a first plate of a capacitor and the second conducting element is a second plate of the capacitor, wherein the first voltage is an AC voltage and the second voltage is ground, wherein the resistor and the capacitor form a circuit with an RC time constant, wherein proximate positions of the plates of the capacitor are selected such that the RC time constant changes when a liquid is in simultaneous contact with the two plates of the capacitor.

Example 14 may be Example 13, further including a liquid cooling system containing the liquid, wherein the liquid cooling system is configured to cool at least one of the computing elements on the substrate, wherein the plates of the capacitor on the substrate are configured to have a leak of the liquid simultaneously contact the two plates when the liquid cooling system has the leak.

Example 15 may be Example 14, wherein a shroud with at least one hole is coupled to the substrate proximate the at least one of the computing elements cooled by the liquid cooling system, wherein the shroud is configured to channel the liquid to the plates of the capacitor when the liquid cooling system leaks at the location of the at least one computing elements cooled by the liquid cooling system.

Example 16 may be Example 8, wherein the substrate is a printed circuit board.

Example 17 may be Example 16, wherein the two conducting elements are interdigitated electrodes comprising metal traces on the printed circuit board.

Example 18 may be Example 8, further including a dry porous pad disposed on the two conducting elements.

Example 19 may be Example 18, wherein the dry porous pad is impregnated with a pH reporter compound.

Example 20 may be Example 19, wherein the pH reporter compound is a halochromic chemical species.

Example 21 may be any one of Examples 8-20, wherein the apparatus is a motherboard, a blade server, or a rack server comprising a motherboard having the substrate, the computing elements and the first and second conducting elements.

Example 22 may a method for detecting liquid leak in a computing node (method) of a rack computing system. The method may include providing a first conducting element on a substrate of the computing node, and coupling the first conducting element to a resistor coupled to a first voltage; providing a second conducting element on the substrate, proximately located near the first electrode, and coupling the second electrode to a second voltage; and placing the substrate with the first and second conducting elements in a computer system having a liquid cooling system containing a liquid, wherein the proximate positions of the first and second conducting elements are selected such that voltage across the conducting elements changes when the liquid leaks from the liquid cooling system and is in simultaneous contact with the two conducting elements.

Example 23 may be Example 22, further including providing a controller coupled with the first and second conducting elements for reporting when the voltage change across the conducting elements moves toward zero when the liquid leaks from the liquid cooling system and is in simultaneous contact with the two conducting elements.

Example 24 may be Example 23, further including providing a controller coupled with the first and second conductive elements, the liquid cooling system and a power supply of the computing node, for turning off or providing a notification to turn off the power supply to the computing node and the liquid cooling system that cools the computing node to prevent the liquid from damaging the computing node.

Example 25 may be Example 24, further including providing a dry adsorbent pad disposed on the two conducting elements.

Example 26 may be Example 25, further including providing a pH reporter compound on the dry adsorbent pad.

Example 27 may be a method for detecting a leak of a cooling liquid at a computing node in a liquid cooled computing system. The method may include holding first and second conductive elements at different electric potentials, wherein the conductive elements are proximately disposed on a substrate at a computing node of the computing system; and detecting when an electric circuit is closed between the two conductive elements resulting from a leak of the cooling liquid when the liquid is in simultaneous contact with the two electrodes.

Example 28 may be Example 27, further including reporting the leak of the liquid.

Example 29 may be Example 28, further including turning off electrical power to the computing node and the liquid cooling system that cools the computing node to prevent the cooling liquid from damaging the computing node.

Example 30 may be Example 29, further including reporting pH of the cooling liquid using an adsorbent pad in contact with the conductive elements and impregnated with a pH reporter compound.

What is claimed is:

1. A rack system for computing, comprising:
a plurality of server boards, wherein at least one of the server boards has a cooling system and a circuit for detecting a leak of a liquid in a cooling system, the circuit comprising:
a first conducting element disposed on a substrate that is coupled to a first voltage; and
a second conducting element disposed on the substrate and coupled to a second voltage,
wherein the first and second conducting elements are proximately disposed near each other, and the proximate positions are selected such that voltage across the conducting elements changes when a liquid is in simultaneous contact with the two conducting elements.

2. The rack system of claim 1, wherein the liquid is a conductive liquid, the two conducting elements are interdigitated electrodes, a resistor is coupled between the first conducting element and the first voltage, and the voltage across the conducting elements moves toward zero when a liquid is in simultaneous contact with the two interdigitated electrodes.

3. The rack system of claim 2, wherein the first voltage is ground and the second voltage is an integrated circuit power supply voltage (V_{cc}), wherein the proximate positions are selected such that voltage of the first electrode becomes non-zero when a conductive liquid is in simultaneous contact with the two interdigitated electrodes.

4. The rack system of claim 1, wherein the first conducting element is a first plate of a capacitor and the second conducting element is a second plate of the capacitor, wherein the first voltage is an AC voltage and the second voltage is ground, wherein the resistor and the capacitor form a circuit with an RC time constant, wherein proximate positions of the plates of the capacitor are selected such that the RC time constant changes when the liquid is in simultaneous contact with the two plates of the capacitor.

5. The rack system of claim 1, further comprising a dry porous pad disposed on the two conducting elements.

6. The rack system of claim 5, wherein the dry porous pad is impregnated with a pH reporter compound.

7. An apparatus for computing, comprising:
a plurality of computing boards, wherein at least one of the computing boards includes:
a substrate;
one or more computing elements disposed on the substrate;
a first conducting element disposed on the substrate that is coupled to a first voltage; and
a second conducting element disposed on the substrate and coupled to a second voltage,
wherein the first and second conducting elements are proximately disposed near each other, and the proximate positions are selected such that voltage across the conducting elements changes when a liquid is in simultaneous contact with the two conducting elements.

8. The apparatus of claim 7, wherein the liquid is a conductive liquid, the two conducting elements are interdigitated electrodes, a resistor is coupled between the first conducting element and the first voltage, and the voltage across the conducting elements moves toward zero when a liquid is in simultaneous contact with the two interdigitated electrodes.

9. The apparatus of claim 8, wherein the first voltage is ground and the second voltage is an integrated circuit power supply voltage (V_{cc}), wherein the proximate positions are selected such that voltage of the first electrode becomes non-zero when a conductive liquid is in simultaneous contact with the two interdigitated electrodes.

10. The apparatus of claim 9, further comprising:
a liquid cooling system containing the conductive liquid,
wherein the liquid cooling system is configured to cool at least one of the computing elements on the substrate,
wherein the electrodes on the substrate are configured to have a leak of the conductive liquid simultaneously contact the two electrodes when the liquid cooling system has the leak.

11. The apparatus of claim 10, wherein a shroud with at least one hole is coupled to the substrate proximate to at least one of the computing elements cooled by the liquid cooling system, wherein the shroud is configured to channel the conductive liquid to the electrodes when the liquid cooling system leaks at the location of the at least one computing elements cooled by the liquid cooling system.

12. The apparatus of claim 7, wherein the first conducting element is a first plate of a capacitor and the second conducting element is a second plate of the capacitor, wherein the first voltage is an AC voltage and the second voltage is ground, wherein the resistor and the capacitor form a circuit with an RC time constant, wherein proximate positions of the plates of the capacitor are selected such that the RC time constant changes when a liquid is in simultaneous contact with the two plates of the capacitor.

13. The apparatus of claim 12, further comprising:
a liquid cooling system containing the liquid,
wherein the liquid cooling system is configured to cool at least one of the computing elements on the substrate,
wherein the plates of the capacitor on the substrate are configured to have a leak of the liquid simultaneously contact the two plates when the liquid cooling system has the leak.

14. The apparatus of claim 13, wherein a shroud with at least one hole is coupled to the substrate proximate the at least one of the computing elements cooled by the liquid cooling system, wherein the shroud is configured to channel the liquid to the plates of the capacitor when the liquid cooling system leaks at the location of the at least one computing elements cooled by the liquid cooling system.

15. The apparatus of claim 7, wherein the substrate is a printed circuit board.

16. The apparatus of claim 15, wherein the two conducting elements are interdigitated electrodes comprising metal traces on the printed circuit board.

17. The apparatus of claim 7, further comprising:
a dry porous pad disposed on the two conducting elements.

18. The apparatus of claim 17, wherein the dry porous pad is impregnated with a pH reporter compound.

19. The apparatus of claim 18, wherein the pH reporter compound is a halochromic chemical species.

20. The apparatus of claim 7, wherein the apparatus is a motherboard, a blade server, or a rack server comprising a motherboard having the substrate, the computing elements and the first and second conducting elements.

21. A method for detecting liquid leak in a computing node within a rack server system, comprising:
providing a first conducting element on a substrate of a computing node within a rack server system, and coupling the first conducting element to a resistor coupled to a first voltage;
providing a second conducting element on the substrate, proximately located near the first electrode, and coupling the second electrode to a second voltage; and
placing the substrate with the first and second conducting elements in a computer system having a liquid cooling system containing a liquid,
wherein the proximate positions of the first and second conducting elements are selected such that voltage across the conducting elements changes when the liquid leaks from the liquid cooling system and is in simultaneous contact with the two conducting elements.

22. The method of claim 21, further comprising:
providing a controller coupled with the first and second conducting elements for reporting when the voltage change across the conducting elements moves toward zero when the liquid leaks from the liquid cooling system and is in simultaneous contact with the two conducting elements.

23. The method of claim 22, further comprising:
providing a controller coupled with the first and second conductive elements, the liquid cooling system and a power supply of the computing node, for turning off or providing a notification to turn off the power supply to the computing node and the liquid cooling system that cools the computing node to prevent the liquid from damaging the computing node.

24. A method for detecting a leak of a cooling liquid at a computing node in a liquid cooled computing system, comprising:
holding first and second conductive elements at different electric potentials, wherein the conductive elements are proximately disposed on a substrate at a computing node of the computing system; and
detecting when an electric circuit is closed between the two conductive elements resulting from a leak of the cooling liquid when the liquid is in simultaneous contact with the two electrodes.

25. The method of claim 24, further comprising:
reporting the leak of the liquid.
